(19) United States
(12) Patent Application Publication
(10) Pub. No.: US 2015/0346251 A1
(43) Pub. Date: Dec. 3, 2015

(54) DETECTOR CIRCUIT

(71) Applicant: QUALCOMM Technologies, Inc., San Diego, CA (US)

(72) Inventors: Peter van DER CAMMEN, Berkel en Rodenrijs (NL); Franco C. FRITSCHIJ, Rijswijk (NL)

(21) Appl. No.: 14/758,970

(22) PCT Filed: Jan. 10, 2013
(86) PCT No.: PCT/EP2013/050413

§ 371 Date: Jul. 2, 2015

(51) Int. Cl. G01R 25/04

(52) U.S. Cl. CPC G01R 25/04

(57) ABSTRACT

A detector circuit for determining an unknown load impedance (Zₓ) without the need for a signal level detector is provided. The detector circuit comprises a phase detector to derive two phase differences (α, β) between three input signals (V₁₂, V₁₀, V₂₀) and a calculation circuit to derive a signal ratio.

The present invention relates to detector circuits, e.g. for impedance measurement systems of mobile communication devices.

### TECHNICAL BACKGROUND

Impedance measurement systems can be used to determine the impedance of a signal path in a mobile communication device where the signal path's impedance depends on its external conditions. In other words: where the signal path has a variable load impedance.

In the case of mobile communication devices with an antenna, the variable load impedance can be due to the antenna's changing environment.

In order to optimize the transmission coefficient of Tx or Rx signals propagating in the signal path, the signal path's actual impedance must be known.

Conventional impedance measurement systems, e.g. known from patent publication U.S. Pat. No. 6,822,433, uses a phase detector and two additional RSSI-chains as level detectors to determine a variable load impedance.

It is an object of the present invention to provide an alternative detector circuit without the need for a level detector, e.g. an RSSI-chain.

Therefore, a detector circuit according to claim 1 is provided. Dependent claims provide preferred embodiments of the invention.

Features of the detector circuit shown hereinafter do not exclude each other. The phase detector can comprise each feature in combination with other features in order to provide an individually optimized detector circuit.

### SUMMARY OF THE INVENTION

A detector circuit is provided that comprises a first signal input determined to receive a first signal S₁, a second signal input determined to receive a second signal S₂ having a phase difference a relative to the first signal S₁ and a third signal input determined to receive a third signal S₃ having a phase difference β relative to the first signal S₁. The detector circuit further comprises a phase detector determined to derive the phase differences α and β. Further, the detector circuit comprises a calculation circuit determined to derive a ratio selected from |S₁|/|S₃|, |S₃|/|S₂|, and |S₂|/|₁| and the respective inverse ratios. Derivation of the ratio is achieved by evaluating the two phase differences α and β obtained from the phase detector. Further, the detector circuit comprises a signal output determined to provide the ratio.

Such a detector circuit may be used in an impedance measurement system for a signal path shown in FIG. 2. The signal path SP may be connected to an antenna having a variable load impedance. Such an antenna and its load impedance is represented by an impedance Zₓ. Further, the signal path SP comprises a sensing impedance Zₛₑₙₛₑ which may be an inductive element IE. V₂₀ denotes the voltage drop across the load impedance Zₓ. V₁₂ denotes the voltage drop across the impedance Zₛₑₙₛₑ. V₁₀ is the sum of the voltages V₂₀ and V₁₂: V₁₀=V₂₀+V₁₂. Thus, the impedance of the signal path SP equals the load impedance Zₓ plus the sensing impedance Zₛₑₙₛₑ which may be a known impedance. From FIG. 2, it is clear that Z=Zₛₑₙₛ V₁₀/V₁₂ where V₁₀ and V₁₂ are voltages representable as complex numbers.

In one embodiment, the first signal S₁, the second signal S₂, and the third signal S₃ are voltage or current signals.

Accordingly, in one embodiment of the detector circuit, the first signal S₁ is the voltage V₁₀. The second signal S₂ is the voltage V₂₀. The third signal S₃ is the voltage V₁₂. However, the above relations between S₁, S₂, and S₃ on one hand and V₁₀, V₂₀, and V₁₂ on the other hand are only examples. In particular it is possible that S₁, S₂, and S₃ are chosen arbitrarily. In other words: From three input signals two arbitrarily chosen different phase differences are needed to determine the last phase difference and to obtain full information about impedances and impedance matching.

Further, it is clear that the situation shown in FIG. 2 can be described with parameters other than voltages V₁₀, V₁₂, and V₂₀. The central idea of the present invention does not depend on details of parameters used as signal inputs for the detector circuit. Other parameters are also possible.

It was found that the problem of deriving the unknown impedance Z can be reduced to determining the ratio V₁₀/V₁₂. V₁₀ may be written as V₁₀=|V₁₀|exp(jωt). Then, V₁₂ may be written as V₁₂=|V₁₂|exp((jωt)+φ), i.e. V₁₀ and V₁₂ are signals of the same frequency with a phase difference of φ between V₁₀ and V₁₂. Accordingly, the ratio V₁₀/V₁₂ can be written as V₁₀/V₁₂=|V₁₀|/|V₁₂|exp(jφ). The correlations between V₁₀, V₁₂, and V₂₀ are visualized in a complex plane view in FIG. 9. Then, α can be ψ, β can be φ and the phase difference between the second signal S₂ and the third signal S₃ γ, i.e. the difference χ=180°−ψ−β, can be the difference γ=180°−β−α. In particular, it is possible that S₁=S₂+S₃.

The problem of deriving the ratio V₁₀/V₁₂ can, thus, be reduced to derive the ratio of the absolute values |V₁₀|/|V₁₂| and by measuring the phase difference φ.

The circuit known from U.S. Pat. No. 6,822,433 uses two RSSI-chains to obtain the ratio of the absolute values. A further phase detector is needed to obtain phase information.

The central idea of the present invention is based on the fact that knowing the values of phase differences φ and ψ intrinsically also comprise information about the ratio of the absolute values |V₁₀|/|V₁₂|. Generally: by knowing two phase differences between two sets of the three input signals S₁, S₂ and S₃, one can calculate any ratio between two absolute levels from the set of S₁, S₂ and S₃. One important aspect of the invention is that circuitry is provided that allows direct access to phase information by processing the three signals V₁₀, V₁₂, and V₂₀.

Especially, the invention is based on the fact that the inventors have found a geometric correlation between signal levels and phase information on one hand and electric circuitry that allows to make use of this correlation on the other hand.

It was found that the following identity (sine rule):

|V₁₀|/|V₁₂|=sin(χ)/sin(ψ)=sin(ψ+φ)/sin(ψ)

allows to directly obtain the ratio of the absolute values of signals V₁₀ and V₁₂ as the three input signals can be interpreted according to FIG. 9. It is clear that with the same geometric correlation, respective other ratios of inputs of the absolute values of input signals can be obtained and utilized for impedance measurement systems in which the detector circuit can be integrated.

The phase detector of the detector circuit provides the phase differences φ and ψ. The third phase difference χ can either be measured as the phase difference between the second signal S₂ and the third signal S₃. However, it is possible to calculate the value for χ as φ+ψ+χ=180°. Further, the respective ratios of the complex numbers can be obtained also.

In one embodiment, the phase detector works in the analog domain or in the digital domain. If the phase detector works in the digital domain, then the detector circuit comprises an analog/digital-converter. The analog/digital-converter can digitalize the values of α and β. Calculation of the ratios and of the third phase difference χ, respectively, can be performed via conventional integrated circuits, e.g. of an ASIC (ASIC=Application-Specific Integrated Circuit).

In one embodiment, the calculation circuit works in the digital domain and the phase detector comprises an analog/digital-converter. Then, signals encoding phase difference information can be obtained via an analog circuit and digitalized via the analog/digital-converter. However, it is also possible that the phase detector itself works in the digital domain and comprises the analog/digital-converter at its signal input.

In one embodiment, the calculation circuit determines the three ratios: S₁/S₃, S₃/S₂, and S₂/S₁.

Each of the three ratios can be expressed as a ratio of the other two ratios or the respective inverse ratio. Thus, the respective measured third ratio can be utilized to improve the accuracy of the other two ratios by comparison with the to be expected third ratio.

In one embodiment, the calculation circuit determines the phase difference of the second signal S₂ relative to the third signal S₃. In other words: the calculation circuit determines the value for the third angle, χ. By summing all three phase differences, the correctness of the measured phase differences can easily be determined as the sum of the phase differences should equal 180°.

In one embodiment, the calculation circuit utilizes a lookup table. Via a lookup table, a digitalized value representing the phase difference can easily be converted into the direct digital representation of the angle's value.

In one embodiment, the detector circuit provides information about a positive ratio selected from: |S₁|/|S₃|, |S₃|/|S₂|, |S₂|/|S₁|. The detector circuit provides information about the phase difference α, β, and/or γ. It is possible that the detector circuit is an impedance detector.

The phase detector can be implemented using limiter amplifiers. Limiter amplifiers create square wave signals which can be processed by conventional phase detector circuits. The use of limiter amplifiers before the conventional phase detectors eliminate amplitude information and ensures that the phase detector circuits work properly. It is possible that a first phase detector circuit determines β while at the same time a second phase detector circuit determines α. However, it is possible that one and the same phase detector circuit provides β and α one after another. Then, a switching circuit can be utilized to provide the single phase detector circuit with different input signals. Only one absolute ratio and one angle is sufficient to provide a ratio Sₓ/S_{y} (x, y=1, 2, or 3) with which the impedance Z can be determined when the impedance Zₛₑₙₛₑ is known.

However, measuring and determining alternative ratios and phase differences can be used to improve the accuracy of the detector circuit.

Examples of the detector circuit, its basic principles and ideas are shown in the schematic figures.

### BRIEF DESCRIPTION OF THE FIGURES

FIG. 1 schematically shows the basic concept of the detector circuit,

FIG. 2 shows an equivalent circuit diagram of a signal path comprising an unknown load impedance Zₓ and a sensing impedance Zₛₑₙₛₑ,

FIG. shows an embodiment of the detector circuit with the calculation circuit CC between the phase detector PD and an analog/digital-converter ADC,

FIG. 4 shows an embodiment of the detector circuit with an analog/digital-converter ADC between the phase detector PD and the calculation circuit CC,

FIG. 5 shows an embodiment of the detector circuit with the phase detector PD between an analog/digital-converter ADC and the calculation circuit CC,

FIG. 6 shows an embodiment of the detector circuit with a combination of phase detectors PD and analog/digital-converters ADC,

FIG. 7 shows an embodiment of the detector circuit with the calculation circuit CC between two phase detector circuits PD and an analog/digital-converter ADC,

FIG. 8 shows an embodiment of the detector circuit with a switching circuit SW before the phase detector PD,

FIG. 9 shows fundamental correlations between the different input signals and their respective phase differences.

### DETAILED DESCRIPTION

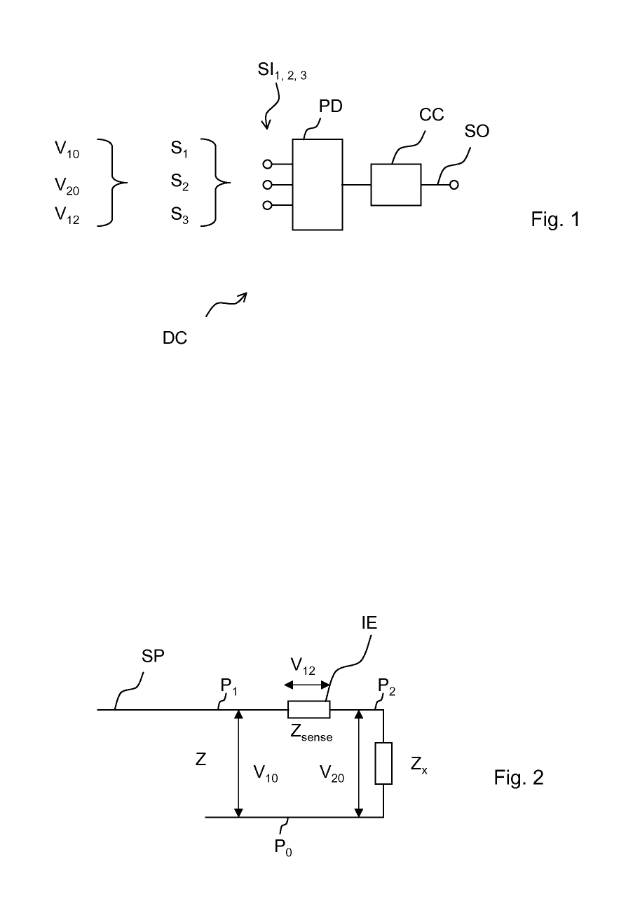

FIG. 1 schematically shows an embodiment of the detector circuit DC comprising three signal inputs SI₁, SI₂, SI₃. Each signal input SI is determined to receive a respective input signal S₁, S₂, and S₃. A phase detector PD derives at least two out of three phase differences, e. g. the phase differences β between the first input signal S₁ and the third input signal S₃ and the phase difference α between the second signal S₂ and the first signal S₁. The derived phase differences α and β are fed into a calculation circuit CC which derives at least one of the ratios |S₁|/|S₃|, |S₃|/|S₂|, and |S₂|/|S₁| or the respective inverse ratio. The ratio or ratios, possibly in combination with the measured phase differences, is provided at a signal output SO which can then be utilized by other circuits, e.g. of a mobile communication device.

Thus, only a phase detector PD and a calculation circuit CC are needed to provide a detector circuit for an impedance measurement system. No additional RSSI-chains providing direct level information are needed.

FIG. 2 schematically shows a signal path SP in which radio frequency signals may propagate. A potentially variable load impedance is denoted as Zₓ. Further, the signal path SP comprises a sensing element Zₛₑₙₛₑ needed for determining phase information. The sensing impedance Zₛₑₙₛₑ could be established by an inductive element IE. V₁₀, V₂₀, and V₁₂ could be the differences between the potentials P₀, P₁, and P₂, respectively.

In the circuit shown in FIG. 2, when the signals V₁₀, V₁₂, and V₂₀ are voltages, then V₁₀=V₁₂+V₂₀.

FIG. 3 shows an embodiment of the detector circuit further comprising an analog/digital-converter ADC. The analog/digital-converter ADC is connected between the calculation circuit CC and the signal output SO. The phase detector PD and the calculation circuit CC can work in the analog domain and the signal output of the calculation circuit can be digitalized by the analog/digital-converter ADC which provides digital information about the actual load impedance Zₓ at the signal output SO.

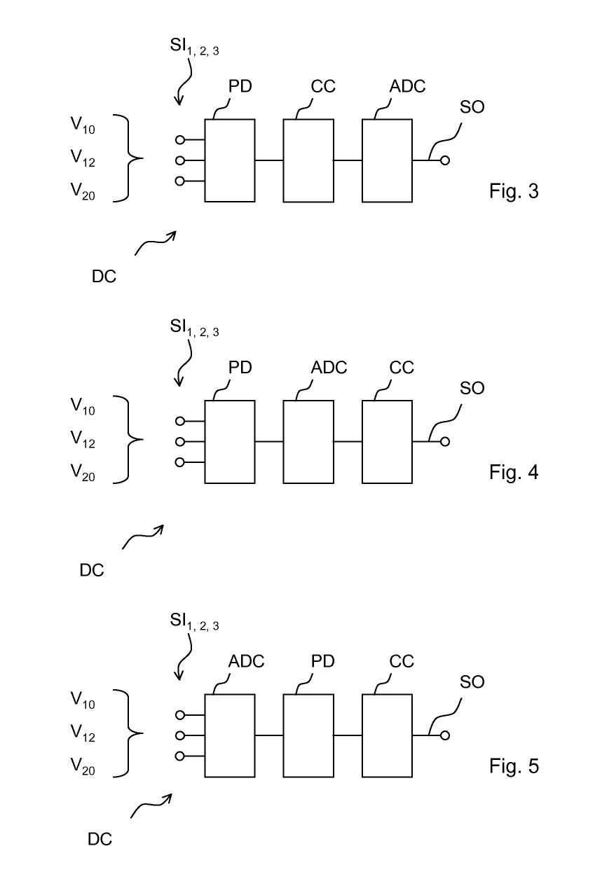

FIG. 4 shows an embodiment of the detector circuit where the analog/digital-converter ADC is connected between the phase detector PD and the calculation circuit CC. Thus, the phase detector PD can work in the analog domain while the calculation circuit CC can work in the digital domain.

FIG. 5 shows an embodiment of the detector circuit where the signal inputs SI are directly connected to an analog/digital-converter ADC. Then, the phase detector PD and the calculation circuit CC can work in the digital domain. The input signals are digitalized by the analog/digital-converter and the derivation of phase differences and the calculation of the signal ratios are performed by integrated circuits, which may be comprised by an ASIC (Application-Specific Integrated Circuit).

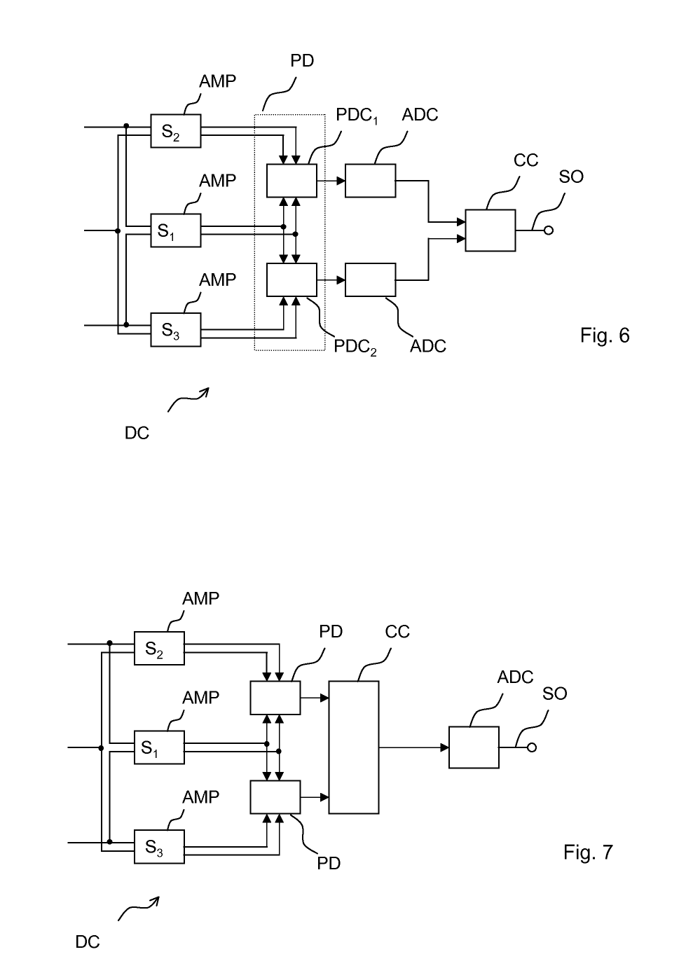

FIG. 6 shows an embodiment of the detector circuit DC comprising amplifiers AMP for preprocessing the input signals before they are fit to the phase detector. The amplifiers AMP may be limiter amplifiers which provide square wave signals to the phase detector PD. The phase detector PD can comprise two phase detector circuits PDC₁, PDC₂. Each of the two phase detector circuits derives a phase difference and transmits the phase difference to an analog/digital-converter ADC. The first phase detector circuit PDC1 derives the phase difference between the first input signal S₁ and the second input signal S₂. The second phase detector circuit PDC2 derives the phase difference between the third input signal S₃ and the first input signal S₁. The respective phase difference is transmitted to a second analog/digital-converter ADC. It is, however, possible that both phase detector circuits transmit the respective phase difference one after the other to one and the same analog/digital-converter ADC. The digitalized information is transferred to the calculation circuit CC which provides phase information, ratio information, or impedance information at the signal output SO.

The input signals S₁, S₂, S₃ can arbitrarily be chosen from the available input signals, e.g. from the input signals a circuit as shown in FIG. 2 provides.

FIG. 7 shows an embodiment of the detector circuit DC where the derived phase information is directly transferred to the calculation circuit CC. The output of the calculation circuit CC is digitalized by the analog/digital-converter ADC.

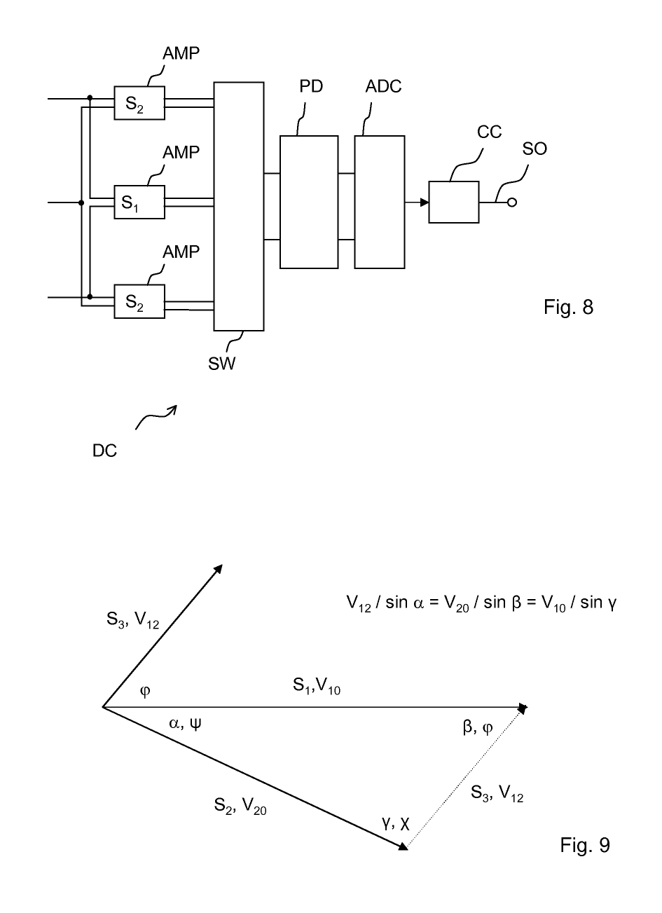

FIG. 8 shows an embodiment of the detector circuit where a switching circuit SW is connected between the signal inputs and the phase detector PD. The switching circuit SW can be utilized to connect different signal inputs with the phase detector PD. Such a switching circuit SW allows to provide a phase detector PD or an analog/digital-converter ADC with only a single signal path as the input signals can be connected to the phase detector PD one after the other. Thus, phase detectors PD, analog/digital-converters ADC and calculation circuits CC having a less complex inner construction, which are cheaper to produce, are possible.

FIG. 9 shows a possible correlation between the input signals S₁, S₂ and S₃ and voltages obtained from a type of circuits as shown in FIG. 2 V₁₀, V₁₂, and V₂₀. V₁₂ could be the voltage drop across the sensing element Zₛₑₙₛₑ, which may be an inductive element. V₁₀ may be the voltage between the input of the signal path and the ground potential. V₂₀ is the voltage drop across the unknown load impedance Zₓ. I. e., V₁₀ is the sum of the voltages V₁₂ and V₂₀. Accordingly, the three voltages establish a triangle defined by the length of the vectors and the respective angles. When from this triangle two values from the set of six values (three angles, three ratios of side lengths) are known, the other four can be calculated.

As a result of the inventors' findings, an alternative detector circuit is provided that makes the use of RSSI-chains or any other circuitry for level ratio detection dispensable.

The detector circuit is not limited to the embodiments described in the specification or shown in the figures. Detector circuits comprising further elements such as further phase detectors, calculation circuits, analog/digital-converters and further switches or impedance elements or combinations thereof are also comprised by the present invention.

The features shown above do not exclude each other. The detector circuit can comprise each feature in combination with other features to obtain an especially optimized detector circuit.

### LIST OF REFERENCE SYMBOLS

α, β, γ: phase differences between input signals S₁, S₂, S₃
ADC: analog/digital-converter
AMP: amplifier
CC: calculation circuit
DC: detector circuit
IE: inductive element
P_{0,1,2}: potentials
PD: phase detector
PDC₁, PDC₂: first, second phase detector circuit
φ, χ, ψ: phase differences between voltages V₁₀, V₁₂, V₂₀
S₁, S₂, S₃: first, second, third input signal
SI_{1,2,3}: first, second, third signal input
SO: signal output
SP: signal path
SW: switching circuit
V₁₀, V₁₂, V₂₀: voltages
Zₛₑₙₛₑ: sensing impedance
Zₓ: load impedance

1. A detector circuit, comprising;
a first signal input determined to receive a first signal S₁;
a second signal input determined to receive a second signal S₂ having a phase difference α relative to the first signal S₁;
a third signal input determined to receive a third signal S₃ having a phase difference β relative to the first signal S₁;
a phase detector determined to derive the phase differences α and β;
a calculation circuit determined to derive a ratio selected from |S₁|/|S₃|, |S₃/|S₂|, and |S₂|/|₁| and the respective inverse ratios thereof by evaluating the two phase differences α and β obtained from the phase detector; and
a signal output determined to provide the ratio.

2. The detector circuit of claim 1, wherein the first signal S₁, the second signal S₂, and the third signal S₃ are voltage or current signals.

3. The detector circuit of claim 1, wherein:
the first signal S₁ is a voltage V₁₀ measured across a serial connection of a sensing impedance Zₛₑₙₛₑ and a further impedance Zₓ;
the third signal S₃ is a voltage V₁₂ measured across the sensing impedance Zₛₑₙₛₑ; and
the second signal S₂ is a voltage V₂₀ measured across the further impedance Zₓ.

4. The detector circuit of claim 1, wherein:
the phase detector works in one of the analog analogue domain and the digital domain; and
the detector circuit comprises an Analog/Digital-converter.

5. The detector circuit of claim 1, wherein:
the calculation circuit works in one of the analog domain and the digital domain; and
the phase detector comprises an Analog/Digital-converter.

6. The detector circuit of claim 1, wherein:
the calculation circuit determines 3 ratios: |S₁|/|S₃|, |S₃|/|S₂|, and |S₂|/|S₁|; and
one ratio is utilized to improve the accuracy of the other two ratios.

7. The detector circuit of claim 1, wherein
the calculation circuit determines the phase difference γ of the second signal S₂ relative to the third signal S₃ to increase accuracy.

8. The detector circuit of claim 1, wherein
the calculation circuit utilizes a lookup table.

9. The detector circuit of claim 1, wherein the detector circuit:
provides information about a positive ratio selected from: |S₁|/|S₃|, |S₃|/|S₂|, |S₂|/|S₁|;
provides information about the phase difference α, β, and/or γ; and
is an impedance detector.
